(19) United States
(12) Patent Application Publication
(10) Pub. No.: US 2026/0019057 A1
(43) Pub. Date: Jan. 15, 2026

(54) APPARATUS AND SYSTEMS FOR A DETECTOR CELL IN A SUCCESSIVE DETECTION LOGARITHMIC AMPLIFIER

(71) Applicant: Texas Instruments Incorporated, Dallas, TX (US)

(72) Inventors: Manoj Pal, Kolkata (IN); Purnendu Bhattaru, Bangalore (IN)

(21) Appl. No.: 19/007,034

(22) Filed: Dec. 31, 2024

(30) Foreign Application Priority Data
Jul. 10, 2024 (IN) 202441052848

(51) Int. Cl. H03G 7/00; H03G 7/06

(52) U.S. Cl. CPC H03G 7/001; H03G 7/06

(57) ABSTRACT

An example detector cell includes a first current source circuit having a terminal. The detector cell includes a first transistor having a control terminal, a first terminal, and a second terminal coupled to the terminal of the first current source circuit. The detector cell includes a second current source circuit having a terminal coupled to the first terminal of the first transistor. The detector cell includes a first current mirror having a first terminal and a second terminal, the first terminal coupled to the terminal of the second current source circuit and the first terminal of the first transistor. The detector cell includes a second transistor having a control terminal, a first terminal, and a second terminal coupled to the terminal of the first current source circuit. The detector cell includes a third current source circuit having a terminal coupled to the first terminal of the second transistor. The detector cell includes a second current mirror having a first terminal coupled to the terminal of the third current source circuit and the first terminal of the second transistor and a second terminal coupled to the second terminal of the first current mirror.

### CROSS-REFERENCE TO RELATED APPLICATION

This patent application claims the benefit of and priority to Indian Provisional Patent Application No. 202441052848 filed Jul. 10, 2024, which Application is hereby incorporated herein by reference in its entirety.

### TECHNICAL FIELD

This description relates generally to detectors and, more particularly, to apparatus and systems for a detector cell in a successive detection logarithmic amplifier.

### BACKGROUND

An amplifier, sometimes referred to as an amp, is an electronic device that can increase the magnitude of a signal. For example, an amplifier increases the amplitude or magnitude of the voltage or current of a signal applied to the inputs of the amplifier and produces a proportionally greater amplitude signal at the outputs of the amplifier. The amount of amplification provided by an amplifier is referred to as gain of the amplifier. For example, the gain of an amplifier refers to the ratio of the output voltage, current, or power signals to the input voltage, current, or power signals of the amplifier. An amplifier may be classified as a common terminal amplifier, a unilateral or bilateral amplifier, an inverting or non-inverting amplifier, or by a gain function of the amplifier. An example of a function-based amplifier is a logarithmic amplifier that produces an output signal that is logarithmically related to an input signal.

### SUMMARY

For apparatus and systems for a detector cell in a successive detection logarithmic amplifier, an example detector cell includes a first current source circuit having a terminal. The detector cell includes a first transistor having a control terminal, a first terminal, and a second terminal coupled to the terminal of the first current source circuit. The detector cell includes a second current source circuit having a terminal coupled to the first terminal of the first transistor. The detector cell includes a first current mirror having a first terminal and a second terminal, the first terminal coupled to the terminal of the second current source circuit and the first terminal of the first transistor. The detector cell includes a second transistor having a control terminal, a first terminal, and a second terminal coupled to the terminal of the first current source circuit. The detector cell includes a third current source circuit having a terminal coupled to the first terminal of the second transistor. The detector cell includes a second current mirror having a first terminal coupled to the terminal of the third current source circuit and the first terminal of the second transistor and a second terminal coupled to the second terminal of the first current mirror. Other examples are described.

For apparatus and systems for a detector cell in a successive detection logarithmic amplifier, an example logarithmic amplifier includes a first detector cell having a first terminal, a second terminal, and a third terminal. The logarithmic amplifier includes an amplifier having a first terminal, a second terminal, a third terminal coupled to the second terminal of the first detector cell, and a fourth terminal coupled to the third terminal of the first detector cell. The logarithmic amplifier includes a second detector cell having a first terminal, a second terminal coupled to the first terminal of the amplifier, and a third terminal coupled to the second terminal of the amplifier. The logarithmic amplifier includes an adder having a first terminal, a second terminal coupled to the first terminal of the first detector cell, and a third terminal coupled to the first terminal of the second detector cell, respective ones of the first detector cell and the second detector cell including: a first current source circuit having a terminal; a first transistor having a control terminal, a first terminal, and a second terminal, the control terminal to operate as the second terminal of the respective ones of the first detector cell and the second detector cell, the second terminal coupled to the terminal of the first current source circuit; a second current source circuit having a terminal coupled to the first terminal of the first transistor; a first current mirror having a first terminal coupled to the terminal of the second current source circuit and the first terminal of the first transistor and a second terminal to operate as the first terminal of the respective ones of the first detector cell and the second detector cell; a second transistor having a control terminal, a first terminal, and a second terminal, the control terminal to operate as the third terminal of the respective ones of the first detector cell and the second detector cell, the second terminal coupled to the terminal of the first current source circuit; a third current source circuit having a terminal coupled to the first terminal of the second transistor; and a second current mirror having a first terminal coupled to the terminal of the third current source circuit and the first terminal of the second transistor and a second terminal coupled to the second terminal of the first current mirror and to operate as the first terminal of the respective ones of the first detector cell and the second detector cell. Other examples are described.

For apparatus and systems for a detector cell in a successive detection logarithmic amplifier, an example logarithmic amplifier having a non-linear transfer function includes a first detector cell having a first terminal, a second terminal, and a third terminal, the first detector cell having a first linear transfer function. The logarithmic amplifier includes an amplifier having a first terminal, a second terminal, a third terminal coupled to the second terminal of the first detector cell, and a fourth terminal coupled to the third terminal of the first detector cell. The logarithmic amplifier includes a second detector cell having a first terminal, a second terminal coupled to the first terminal of the amplifier, and a third terminal coupled to the second terminal of the amplifier, the second detector cell having a second linear transfer function. The logarithmic amplifier includes an adder having a first terminal, a second terminal coupled to the first terminal of the first detector cell, and a third terminal coupled to the first terminal of the second detector cell. Other examples are described.

### BRIEF DESCRIPTION OF THE DRAWINGS

FIG. 1A is a block diagram of an example successive detection logarithmic amplifier (SDLA) with differential inputs and differential outputs.

FIG. 1B is a block diagram of the SDLA of FIG. 1A with differential inputs and a single ended output.

FIG. 2A is a graphical illustration of an example graph depicting a relationship between dynamic range (DR) of an SDLA and the gain, A, of each amplifier stage of the SDLA.

FIG. 2B is a graphical illustration of an example graph depicting a relationship between logarithmic conformance error (LCE) of an SDLA and the gain, A, of each amplifier stage of the SDLA.

FIG. 3 is a schematic of an example detector cell in conjunction with examples described herein.

FIG. 4 is a graphical illustration of an example graph depicting a transfer function of the detector cell of FIG. 3.

FIG. 5A is a graphical illustration of an example graph depicting a relationship between a degree of a detector cell and LCE of an SDLA.

FIG. 5B is a graphical illustration of an example graph depicting a relationship between a degree of a detector cell and DR of an SDLA.

FIG. 5C is a graphical illustration of an example graph depicting a relationship between the transfer function of a detector cell and a degree of the detector cell.

The drawings are not necessarily to scale. Generally, the same reference numbers in the drawing(s) and this description refer to the same or similar (at least one of functional or structural) features or parts. Although the drawings show regions with clean lines and boundaries, some or all of these lines and boundaries may be idealized. In reality, the boundaries or lines may be unobservable, blended or irregular.

### DETAILED DESCRIPTION

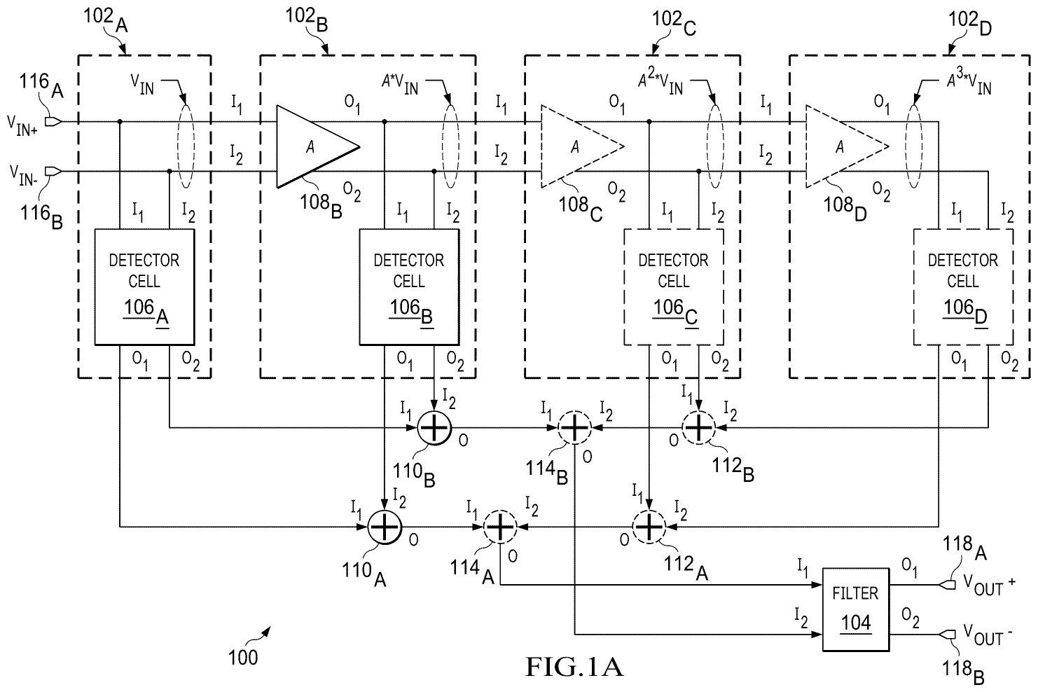

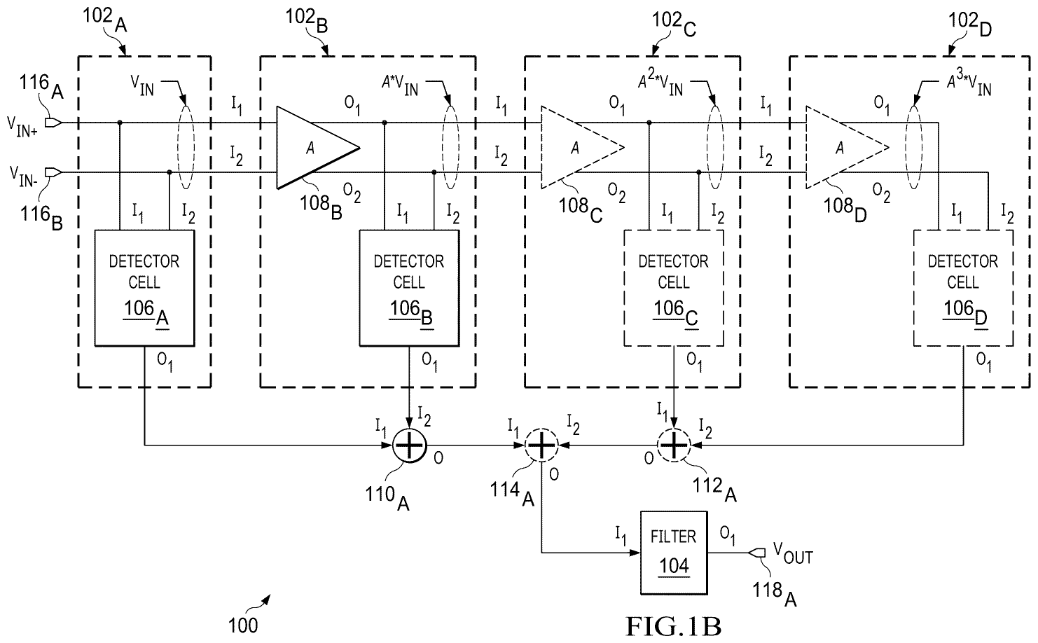

Logarithmic amplifiers, sometimes referred to as log amplifiers, produce an output signal that is logarithmically related to an input signal. One type of logarithmic amplifier is a successive detection logarithmic amplifier (SDLA). SDLAs are widely used to measure signal strength in different received signal strength indicator (RSSI) applications such as ultrasound front-end circuits, energy or power monitoring circuits, or transmit power control circuits. SDLAs are widely used because SDLAs can achieve a wide dynamic range of operation as well as high-speed operation. The architecture of an SDLA includes a cascaded chain of amplifier stages shunted by corresponding detector cells. For example, FIG. 1A is a block diagram of an example SDLA 100 with differential inputs and differential outputs.

In the illustrated example of FIG. 1A, the SDLA 100 includes at least a first example stage 102_{A}, a second example stage 102_{B}, and an example filter 104. In some examples, the SDLA 100 also includes a third example stage 102_{C} and a fourth example stage 102_{D}. As such, the components of the stage 102_{C} and the stage 102_{D} are illustrated with dashed lines. In the example of FIG. 1A, the stage 102_{A} includes a first example detector cell 106_{A}. Also, the stage 102_{B} includes a second example detector cell 106_{B} and a first example amplifier 108_{B}. In the example of FIG. 1A, the stage 102_{C} includes a third example detector cell 106_{C} and a second example amplifier 108_{C}. Also, the stage 102_{D} includes a fourth example detector cell 106_{D} and a third example amplifier 108_{D}. In the example of FIG. 1A, the SDLA 100 also includes a first example adder 110_{A} and a second example adder 110_{B}. In some examples, the SDLA 100 also includes a third example adder 112_{A}, a fourth example adder 112_{B}, a fifth example adder 114_{A}, and a sixth example adder 114_{B}. As such, the adder 112_{A}, the adder 112_{B}, the adder 114_{A}, and the adder 114_{B} are illustrated with dashed lines.

In the illustrated example of FIG. 1A, each of the filter 104, the detector cell 106_{A}, the detector cell 106_{B}, the detector cell 106_{C}, the detector cell 106_{D}, the amplifier 108_{B}, the amplifier 108_{C}, and the amplifier 108_{D} has a first input, a second input, a first output, and a second output. Also, each of the adder 110_{A}, the adder 110_{B}, the adder 112_{A}, the adder 112_{B}, the adder 114_{A}, and the adder 114_{B} has a first input, a second input, and an output. In the example of FIG. 1A, the SDLA 100 has a first example input 116_{A}, a second example input 116_{B}, a first example output 118_{A}, and a second example output 118_{B}.

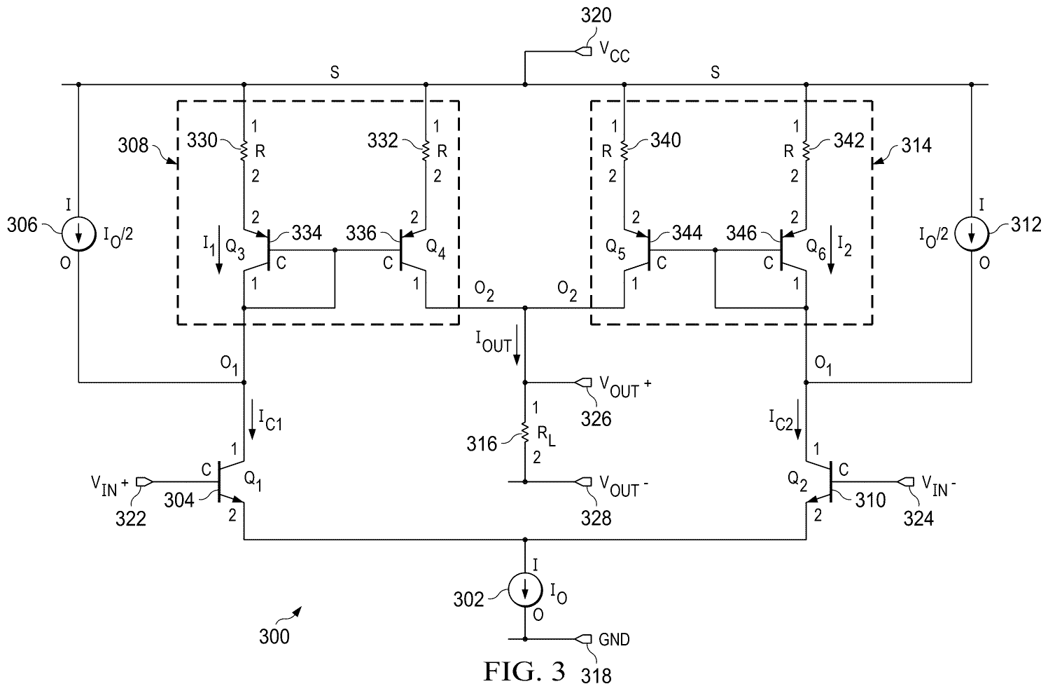

In the illustrated example of FIG. 1A, the filter 104 is implemented by at least one of analog or digital circuitry. In the example of FIG. 1A, each of the detector cell 106_{A}, the detector cell 106_{B}, the detector cell 106_{C}, and the detector cell 106_{D} is implemented as described in connection with FIG. 3 further herein. Also, each of the amplifier 108_{B}, the amplifier 108_{C}, and the amplifier 108_{D} is implemented by at least analog circuitry. In the example of FIG. 1A, each of the adder 110_{A}, the adder 110_{B}, the adder 112_{A}, the adder 112_{B}, the adder 114_{A}, and the adder 114_{B} is implemented by at least one of analog or digital circuitry.

In the illustrated example of FIG. 1A, the first input of the detector cell 106_{A} is coupled to the input 116_{A}, the second input of the detector cell 106_{A} is coupled to the input 116_{B}, the first output of the detector cell 106_{A} is coupled to the first input of the adder 110_{A}, and the second output of the detector cell 106_{A} is coupled to the first input of the adder 110_{B}. Also, the first input of the detector cell 106_{B} is coupled to the first output of the amplifier 108_{B}, the second input of the detector cell 106_{B} is coupled to the second output of the amplifier 108_{B}, the first output of the detector cell 106_{B} is coupled to the second input of the adder 110_{A}, and the second output of the detector cell 106_{B} is coupled to the second input of the adder 110_{B}. In the example of FIG. 1A, the first input of the amplifier 108_{B} is coupled to the input 116_{A}, the second input of the amplifier 108_{B} is coupled to the input 116_{B}, the first output of the amplifier 108_{B} is coupled to the first input of the amplifier 108_{C}, and the second output of the amplifier 108_{B} is coupled to the second input of the amplifier 108_{C}.

In the illustrated example of FIG. 1A, the first input of the detector cell 106_{C} is coupled to the first output of the amplifier 108_{C} and the second input of the detector cell 106_{C} is coupled to the second output of the amplifier 108_{C}. In the example of FIG. 1A, the first output of the detector cell 106_{C} is coupled to the first input of the adder 112_{A} and the second output of the detector cell 106_{C} is coupled to the first input of the adder 112_{B}. In the example of FIG. 1A, the first input of the amplifier 108_{C} is coupled to the first output of the amplifier 108_{B} and the second input of the amplifier 108_{C} is coupled to the second output of the amplifier 108_{B}. Also, the first output of the amplifier 108_{C} is coupled to the first input of the amplifier 108_{D} and the second output of the amplifier 108_{C} is coupled to the second input of the amplifier 108_{D}.

In the illustrated example of FIG. 1A, the first input of the detector cell 106_{D} is coupled to the first output of the amplifier 108_{D} and the second input of the detector cell 106_{D} is coupled to the second output of the amplifier 108_{D}. In the example of FIG. 1A, the first output of the detector cell 106_{D} is coupled to the second input of the adder 112_{A} and the second output of the detector cell 106_{D} is coupled to the second input of the adder 112_{B}. Also, the first input of the amplifier 108_{D} is coupled to the first output of the amplifier 108_{C} and the second input of the amplifier 108_{D} is coupled to the second output of the amplifier 108_{C}. In the example of FIG. 1A, the first output of the amplifier 108_{D} is coupled to the first input of the detector cell 106_{D} and the second output of the amplifier 108_{D} is coupled to the second input of the detector cell 106_{D}.

In the illustrated example of FIG. 1A, the first input of the adder 110_{A} is coupled to the first output of the detector cell 106_{A} and the second input of the adder 110_{A} is coupled to the first output of the detector cell 106_{B}. In the example of FIG. 1A, the output of the adder 110_{A} is coupled to the first input of the adder 114_{A}. Also, the first input of the adder 110_{B} is coupled to the second output of the detector cell 106_{A} and the second input of the adder 110_{B} is coupled to the second output of the detector cell 106_{B}. In the example of FIG. 1A, the output of the adder 110_{B} is coupled to the first input of the adder 114_{B}. In examples where the SDLA 100 does not include the stage 102_{C}, the stage 102_{D}, the adder 112_{A}, the adder 112_{B}, the adder 114_{A}, and the adder 114_{B}, the output of the adder 110_{A} is coupled to the first input of the filter 104 and the output of the adder 110_{B} is coupled to the second input of the filter 104.

In the illustrated example of FIG. 1A, the first input of the adder 112_{A} is coupled to the first output of the detector cell 106_{C} and the second input of the adder 112_{A} is coupled to the first output of the detector cell 106_{D}. In the example of FIG. 1A, the output of the adder 112_{A} is coupled to the second input of the adder 114_{A}. Also, the first input of the adder 112_{B} is coupled to the second output of the detector cell 106_{C} and the second input of the adder 112_{B} is coupled to the second output of the detector cell 106_{D}. In the example of FIG. 1A, the output of the adder 112_{B} is coupled to the second input of the adder 114_{B}.

In the illustrated example of FIG. 1A, the first input of the adder 114_{A} is coupled to the output of the adder 110_{A} and the second input of the adder 114_{A} is coupled to the output of the adder 112_{A}. In the example of FIG. 1A, the output of the adder 114_{A} is coupled to the first input of the filter 104. Also, the first input of the adder 114_{B} is coupled to the output of the adder 110_{B} and the second input of the adder 114_{B} is coupled to the output of the adder 112_{B}. In the example of FIG. 1A, the output of the adder 114_{B} is coupled to the second input of the filter 104.

In the illustrated example of FIG. 1A, the first input of the filter 104 is coupled to the output of the adder 114_{A} and the second input of the filter 104 is coupled to the output of the adder 114_{B}. As described above, in examples where the SDLA 100 does not include the stage 102_{C}, the stage 102_{D}, the adder 112_{A}, the adder 112_{B}, the adder 114_{A}, and the adder 114_{B}, the first input of the filter 104 is coupled to the output of the adder 110_{A} and the second input of the filter 104 is coupled to the output of the adder 110_{B}. In the example of FIG. 1A, the first output of the filter 104 is coupled to the output 118_{A}. In the example of FIG. 1A, the second output of the filter 104 is coupled to the output 118_{B}.

In the illustrated example of FIG. 1A, the SDLA 100 receives an input signal V_{IN} at the input 116_{A} and the input 116_{B} and produces an output signal V_{OUT} at the output 118_{A} and the output 118_{B}. For example, the input signal V_{IN} is measured between the input 116_{A}, which receives a positive input signal V_{IN+}, and the input 116_{B}, which receives a negative input signal V_{IN-}. Also, for example, the output signal V_{OUT} is measured between the output 118_{A} and the output 118_{B}.

In the illustrated example of FIG. 1A, the stage 102_{A} does not apply a gain to the input signal V_{IN}. In the example of FIG. 1A, each of the stage 102_{B}, the stage 102_{C}, and the stage 102_{D} applies a gain of A to an input signal. As such, the output signal from the stage 102_{B} has an amplitude of A*V_{IN}, the output signal from the stage 102_{C} has an amplitude of A²*V_{IN}, and the output signal from the stage 102_{D} has an amplitude of A³*V_{IN}.

In the illustrated example of FIG. 1A, each of the detector cell 106_{A}, the detector cell 106_{B}, the detector cell 106_{C}, and the detector cell 106_{D} rectifies an input signal. For example, if the input signal V_{IN} is an alternating current (AC) signal, then the detector cell 106_{A} rectifies the negative portion of the AC signal to positive values effectively converting the AC signal to a direct current (DC) signal. Also, each of the detector cell 106_{A}, the detector cell 106_{B}, the detector cell 106_{C}, and the detector cell 106_{D} saturates at a saturated voltage V_{L} depending on the voltage of an input signal.

In the illustrated example of FIG. 1A, the adder 110_{A} and the adder 110_{B} sum the differential output signal from the detector cell 106_{A} and the differential output signal from the detector cell 106_{B}. In the example of FIG. 1A, the adder 112_{A} and the adder 112_{B} sum the differential output signal from the detector cell 106_{C} and the differential output signal from the detector cell 106_{D}. Also, the adder 114_{A} sums the output signals from the adder 110_{A} and the adder 112_{A} and the adder 114_{B} sums the output signals from the adder 110_{B} and the adder 112_{B}.

In the illustrated example of FIG. 1A, depending on the amplitude of the input signal V_{IN}, the SDLA 100 amplifies the input signal V_{IN} differently. For example, if the input signal V_{IN} has a small amplitude, then each of the stage 102_{B}, the stage 102_{C}, and the stage 102_{D} are active and the gain, A³, of the stage 102_{D} dominates the overall transfer function of the SDLA 100. Accordingly, if the input signal V_{IN} has a small amplitude, then each of the detector cell 106_{A}, the detector cell 106_{B}, the detector cell 106_{C}, and the detector cell 106_{D} may not saturate.

In the illustrated example of FIG. 1A, if the input signal V_{IN} has a large amplitude, one or more detector cells of the SDLA 100 may saturate at the saturated voltage V_{L}. Accordingly, if the input signal V_{IN} has a large amplitude, then one or more of the detector cell 106_{A}, the detector cell 106_{B}, the detector cell 106_{C}, or the detector cell 106_{D} may saturate one after another. Saturation of one or more of the detector cell 106_{A}, the detector cell 106_{B}, the detector cell 106_{C}, or the detector cell 106_{D} would reduce the gain of the SDLA 100 by a factor of A after each saturation.

For example, assuming the last stage of the SDLA 100, for example, the stage 102_{D}, is saturated, then the output voltage signal V_{OUT} of the SDLA 100 is defined in Equation 1 below.

$${V}_{OUT} = {V}_{L} + \frac{{V}_{L}}{A} + \frac{{V}_{L}}{{A}^{2}} + \frac{{V}_{L}}{{A}^{3}} \qquad Equation 1$$

As such, for a factor of A increase in the magnitude of the input signal V_{IN}, the magnitude of the output signal V_{OUT} increases by the saturated voltage V_{L}. For example, for a factor of A increase in the magnitude of the input signal V_{IN}, then the output voltage signal V_{OUT} of the SDLA 100 is defined in Equation 2 below.

$${V}_{OUT} = 2 * {V}_{L} + \frac{{V}_{L}}{A} + \frac{{V}_{L}}{{A}^{2}} \qquad Equation 2$$

As such, for a constant increase, for example by A, in the input signal V_{IN}, the SDLA 100 has a constant increment, for example by V_{L}, in the output signal V_{OUT}, or, in other words, there is a logarithmic relationship between the input signal V_{IN} and the output signal V_{OUT}. In the example of FIG. 1A, the filter 104 is a low-pass filter that receives the differential output signal from the adder 114_{A} and the adder 114_{B}. As such, the filter 104 produces an average signal of the logarithm of the input signal V_{IN}. For example, the average signal of the logarithm of the input signal V_{IN} may be referred to as a DC signal of the logarithm of the input signal V_{IN}.

While SDLAs are widely used to measure signal strength in different applications, one drawback of SDLAs is the tradeoff between logarithmic conformance error (LCE), minimum input detectability, dynamic range (DR), and the power consumption. LCE is a measure of how closely the transfer function of an SDLA conforms to a logarithmic function. A lower LCE indicates that the transfer function of an SDLA closely conforms to a logarithmic function. Minimum input detectability refers to the smallest signal that an SDLA can detect. The minimum input detectability of an SDLA is defined with respect to an LCE threshold. For example, the LCE of an SDLA being below the LCE threshold ensures that a target input detectability is achieved. DR refers to the range of input signal magnitudes over which an SDLA can accurately produce an output signal that is proportional to the logarithm of the input signal.

For an SDLA having N amplifier stages each with gain A, the DR of the SDLA is A^{N}. As such, for a given number of amplifier stages, N, in an SDLA, the DR is proportional to the gain, A, per amplifier stage of the SDLA. Also, for a given number of amplifier stages, N, in an SDLA, the LCE of the SDLA is proportional to the gain, A, per amplifier stage of the SDLA.

FIG. 1B is a block diagram of the SDLA 100 of FIG. 1A with differential inputs and a single ended output. In the example of FIG. 1B, the detector cell 106_{A}, the detector cell 106_{B}, the detector cell 106_{C}, the detector cell 106_{D}, the amplifier 108_{B}, the amplifier 108_{C}, and the amplifier 108_{D} are implemented and operate similarly as described in FIG. 1A but that the detector cell 106_{A}, the detector cell 106_{B}, the detector cell 106_{C}, and the detector cell 106_{D} have one output instead of two outputs. For example, in FIG. 1B, the output signals provided the detector cell 106_{A}, the detector cell 106_{B}, the detector cell 106_{C}, and the detector cell 106_{D} are measured with respect to a ground terminal instead of between the first outputs and the second outputs of the detector cell 106_{A}, the detector cell 106_{B}, the detector cell 106_{C}, and the detector cell 106_{D}.

As such, the adder 110_{B}, the adder 112_{B}, and the adder 114_{B} can be omitted, which can save space when the SDLA 100 is implemented in silicon. In the example of FIG. 1B, the adder 110_{A}, the adder 112_{A}, the adder 114_{A}, and the filter 104 are implemented and operate similarly as described in FIG. 1A but that the filter 104 has one input and one output instead of two inputs and two outputs. For example, in FIG. 1B, the output signal provided the filter 104 is measured with respect to a ground terminal instead of between the first output and the second output of the filter 104.

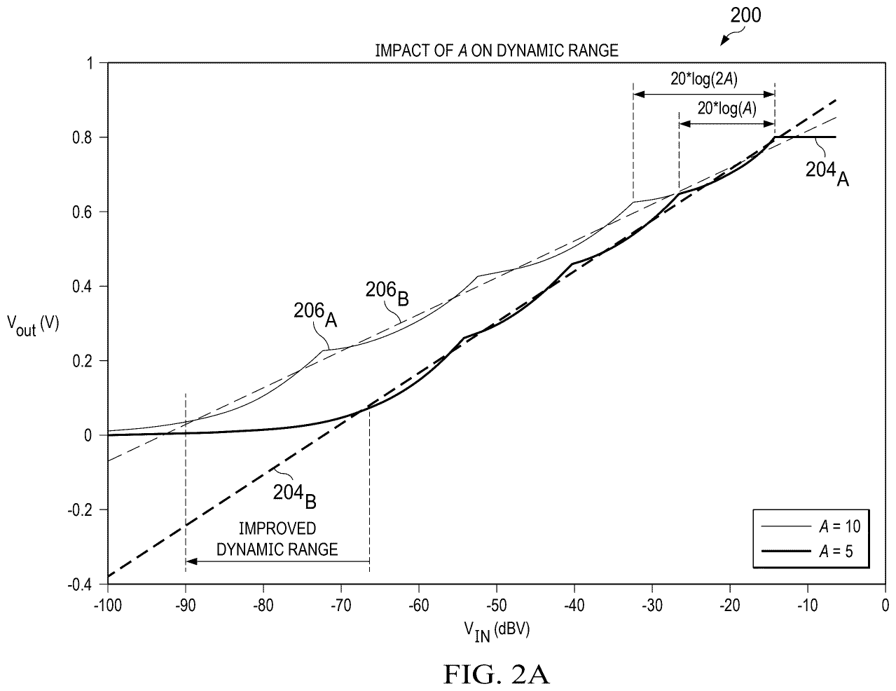

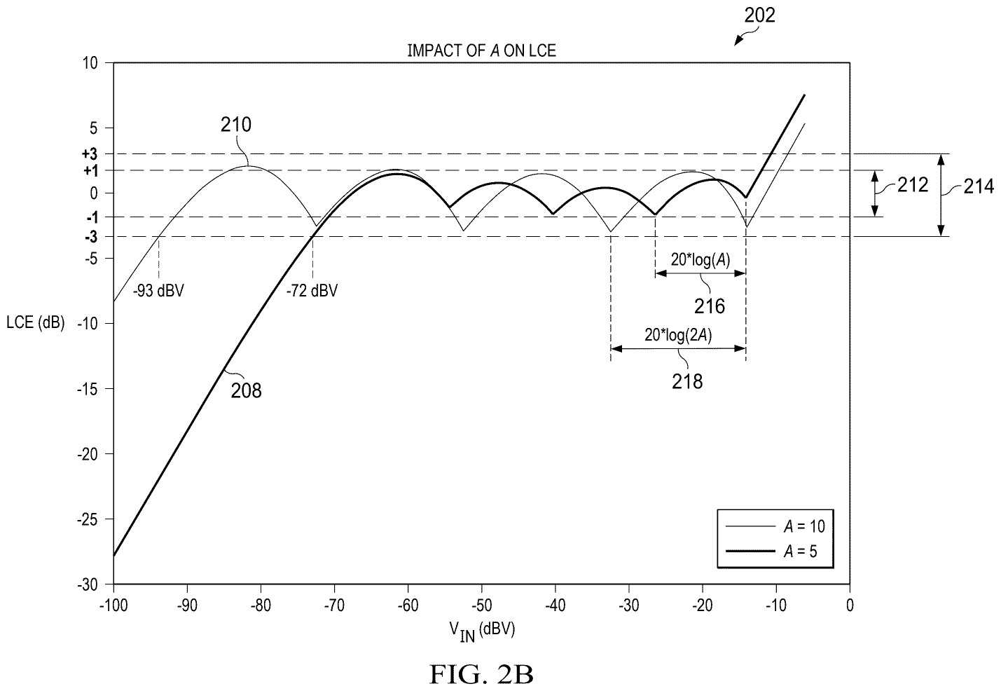

FIG. 2A is a graphical illustration of an example graph 200 depicting a relationship between DR of an SDLA and the gain, A, of each amplifier stage of the SDLA. In the example of FIG. 2A, the graph 200 depicts output voltage signal, also referred to as V_{OUT}, in volts (V) versus input voltage signal, also referred to as V_{IN}, in decibel (dB) voltage scale (dBV). FIG. 2B is a graphical illustration of an example graph 202 depicting a relationship between LCE of an SDLA and the gain, A, of each amplifier stage of the SDLA. In the example of FIG. 2B, the graph 202 depicts output voltage signal, also referred to as V_{OUT}, in volts versus input voltage signal, also referred to as V_{IN}, in dBV.

In the illustrated example of FIG. 2A, the graph 200 includes a first example plot 204_{A} depicting input voltage signal versus output voltage signal of an SDLA with a gain, A, of five in each amplifier stage of the SDLA. In the example of FIG. 2A, the graph 200 includes a second example plot 204_{B} depicting input voltage signal versus output voltage signal of an ideal SDLA with a gain, A, of five in each amplifier stage of the ideal SDLA. Also, the graph 200 includes a third example plot 206_{A} depicting input voltage signal versus output voltage signal of an SDLA with a gain, A, of 10 in each amplifier stage of the SDLA. In the example of FIG. 2A, the graph 200 includes a fourth example plot 206_{B} depicting input voltage signal versus output voltage signal of an ideal SDLA with a gain, A, of 10 in each amplifier stage of the ideal SDLA. As illustrated in FIG. 2A, by increasing the gain per amplifier stage from 5 to 10, the DR of an SDLA can be increased by about 22 dB.

In the illustrated example of FIG. 2B, the graph 202 includes a first example plot 208 depicting input voltage signal versus LCE of an SDLA with a gain, A, of five in each amplifier stage of the SDLA. In the example of FIG. 2B, the graph 202 includes a second example plot 210 depicting input voltage signal versus LCE of an SDLA with a gain, A, of 10 in each amplifier stage of the SDLA. In the example of FIG. 2B, the graph 202 includes a first example LCE threshold 212 within which the SDLA of the plot 208 operates and a second example LCE threshold 214 within which the SDLA of the plot 210 operates. For example, the LCE threshold 212 is ±1 dB and the LCE threshold 214 is ±3 dB.

In the illustrated example of FIG. 2B, the width and height of the lobes of the plot 208 and the plot 210 are indicative of the LCE of the respective SDLAs. For example, a thinner and shorter lobe indicates a lower LCE which indicates that an SDLA can achieve reduced granularity of logarithmic approximation. As illustrated in FIG. 2B, the width and height of a first example lobe 216 of the plot 208 are lower than the width and height of a second example lobe 218 of the plot 210. As such, by decreasing the gain per amplifier stage from 10 to 5, the LCE of an SDLA can be decreased. Thus, if a designer desires to reduce the LCE of an SDLA, one way would be to reduce the gain, A, of each amplifier stage of the SDLA. However, as illustrated in FIG. 2A, reducing the gain, A, of each amplifier stage of an SDLA also reduces the DR of the SDLA. As such, a designer can achieve better LCE at the cost of DR.

Also, if a designer desires to increase the minimum input detectability of an SDLA, one way would be to reduce the LCE of the SDLA around the target minimum input signal. However, if the LCE of an SDLA is reduced by reducing the gain, A, of each amplifier stage of the SDLA, the DR of the SDLA will also be reduced as illustrated in FIGS. 2A and 2B. As such, if a designer wants to maintain the same DR of an SDLA while also reducing the LCE of the SDLA, one way would be to increase the number of amplifier stages, N, of the SDLA. However, increasing the number of amplifier stages, N, of an SDLA would consume more area on a chip and consume more power. Some approaches to improve SDLAs have focused on improving the amplifier stages of an SDLA. For example, if each amplifier stage has a lower noise floor, then an SDLA can include a greater number of amplifier stages to achieve a targeted dynamic range while also achieving detectability of a target minimum input signal.

Examples described herein include a detector cell architecture that improves detector cell non-linearity to improve the LCE of an SDLA for a given gain, A, per amplifier stage of the SDLA without compromising on DR, area consumption on chip, power consumption, or minimum input detectability. Described examples include a detector cell architecture with a linear transfer function that results in the overall piecewise transfer function of an SDLA very closely conforming to a non-linear, logarithmic function. As such, described examples reduce LCE of an SDLA.

FIG. 3 is a schematic of an example detector cell 300 in conjunction with examples described herein. In the example of FIG. 3, the detector cell 300 includes a first example current source 302, a first example transistor 304 (Q₁), a second example current source 306, a first example current mirror 308, a second example transistor 310 (Q₂), a third example current source 312, a second example current mirror 314, and an example load resistor 316. Also, the detector cell 300 of FIG. 3 has a first example voltage terminal 318, a second example voltage terminal 320, a first example input 322, a second example input 324, a first example output 326, and a second example output 328. In some examples, the voltage terminal 318 is referred to as a ground terminal and the voltage terminal 320 is referred to as a supply terminal.

In the illustrated example of FIG. 3, the input 322 receives a positive input signal V_{IN+}, the input 324 receives a negative input signal V_{IN-}, the output 326 provides a positive output signal V_{OUT+}, and the output 328 provides a negative output signal V_{OUT-}. In the example of FIG. 3, the current mirror 308 includes a first example resistor 330, a second example resistor 332, a third example transistor 334 (Q₃), and a fourth example transistor 336 (Q₄). Also, the current mirror 314 includes a third example resistor 340, a fourth example resistor 342, a fifth example transistor 344 (Q₅), and a sixth example transistor 346 (Q₆).

In the illustrated example of FIG. 3, each of the current source 302, the current source 306, and the current source 312 has an input and an output. In some examples, one or more of the current source 302, the current source 306, or the current source 312 is referred to as a current source circuit. In the example of FIG. 3, each of the transistor 304, the transistor 310, the transistor 334, the transistor 336, the transistor 344, and the transistor 346 has a control terminal, a first terminal, and a second terminal. In some examples, the control terminal, the first terminal, and the second terminal of a transistor are referred to as a base terminal, a collector terminal, and an emitter terminal. Also, each of the load resistor 316, the resistor 330, the resistor 332, the resistor 340, and the resistor 342 has a first terminal and a second terminal. In the example of FIG. 3, each of the current mirror 308 and the current mirror 314 has a first output, a second output, and a supply input.

In the illustrated example of FIG. 3, the current source 302 is implemented by at least analog circuitry. For example, the current source 302 is implemented by a bipolar junction transistor (BJT) such as a negative-positive-negative (NPN) BJT. In some examples, the current source 302 is implemented by a field-effect transistor (FET) such as an n-channel metal-oxide-semiconductor (NMOS) FET, also referred to as a negative-channel metal-oxide-semiconductor field-effect transistor. In the example of FIG. 3, the input of the current source 302 is coupled to the second terminal of the transistor 304 and the second terminal of the transistor 310. Also, the output of the current source 302 is coupled to the voltage terminal 318.

In the illustrated example of FIG. 3, the transistor 304 is implemented by a BJT such as an NPN BJT, also referred to as a negative-positive-negative bipolar junction transistor. In some examples, the transistor 304 is implemented by a FET such as an NMOS FET, also referred to as a negative-channel MOSFET. In the example of FIG. 3, the control terminal of the transistor 304 is coupled to the input 322. Also, the first terminal of the transistor 304 is coupled to the output of the current source 306 and the first terminal of the transistor 334, which operates as the first output of the current mirror 308. In the example of FIG. 3, the second terminal of the transistor 304 is coupled to the input of the current source 302.

In the illustrated example of FIG. 3, the current source 306 is implemented by at least analog circuitry. For example, the current source 306 is implemented by a BJT such as a positive-negative-positive (PNP) BJT with a saturation protection clamp. In some examples, the current source 306 is implemented by a FET such as a p-channel metal-oxide-semiconductor (PMOS) FET, also referred to as a positive-channel metal-oxide-semiconductor field-effect transistor. In the example of FIG. 3, the input of the current source 306 is coupled to the voltage terminal 320. Also, the output of the current source 306 is coupled to the first terminal of the transistor 304 and the first terminal of the transistor 334, which operates as the first output of the current mirror 308.

In the illustrated example of FIG. 3, the supply input of the current mirror 308, for example, the first terminal of the resistor 330 and the first terminal of the resistor 332, is coupled to the voltage terminal 320. In the example of FIG. 3, the first output of the current mirror 308, for example, the first terminal of the transistor 334, is coupled to the first terminal of the transistor 304 and the output of the current source 306. Also, the second output of the current mirror 308, for example, the first terminal of the transistor 336, is coupled to the first terminal of the load resistor 316 and the output 326.

In the illustrated example of FIG. 3, the first terminal of the resistor 330, which operates as the supply input of the current mirror 308, is coupled to the voltage terminal 320. In the example of FIG. 3, the second terminal of the resistor 330 is coupled to the second terminal of the transistor 334. Also, the first terminal of the resistor 332, which operates as the supply input of the current mirror 308, is coupled to the voltage terminal 320. In the example of FIG. 3, the second terminal of the resistor 332 is coupled to the second terminal of the transistor 336.

In the illustrated example of FIG. 3, the transistor 334 is implemented by a BJT such as a PNP BJT, also referred to as a positive-negative-positive bipolar junction transistor. In some examples, the transistor 334 is implemented by a FET such as a PMOS FET, also referred to as a positive-channel MOSFET. In the example of FIG. 3, the control terminal of the transistor 334 is coupled to the first terminal of the transistor 334, the first terminal of the transistor 304, the output of the current source 306, and the control terminal of the transistor 336. Also, the first terminal of the transistor 334, which operates as the first output of the current mirror 308, is coupled to the control terminal of the transistor 334, the first terminal of the transistor 304, the output of the current source 306, and the control terminal of the transistor 336. In the example of FIG. 3, the second terminal of the transistor 334 is coupled to the second terminal of the resistor 330.

In the illustrated example of FIG. 3, the transistor 336 is implemented by a BJT such as a PNP BJT, also referred to as a positive-negative-positive BJT. In some examples, the transistor 336 is implemented by a FET such as a PMOS FET. In the example of FIG. 3, the control terminal of the transistor 336 is coupled to the control terminal of the transistor 334, the first terminal of the transistor 334, the first terminal of the transistor 304, and the output of the current source 306. Also, the first terminal of the transistor 336, which operates as the second output of the current mirror 308, is coupled to the first terminal of the load resistor 316 and the output 326. In the example of FIG. 3, the second terminal of the transistor 336 is coupled to the second terminal of the resistor 332.

In the illustrated example of FIG. 3, the transistor 310 is implemented by a BJT such as an NPN BJT, also referred to as a negative-positive-negative BJT. In some examples, the transistor 310 is implemented by a FET such as an NMOS FET. In the example of FIG. 3, the control terminal of the transistor 310 is coupled to the input 324. Also, the first terminal of the transistor 310 is coupled to the output of the current source 312 and the first terminal of the transistor 346, which operates as the first output of the current mirror 314. In the example of FIG. 3, the second terminal of the transistor 310 is coupled to the input of the current source 302.

In the illustrated example of FIG. 3, the current source 312 is implemented by at least analog circuitry. For example, the current source 312 is implemented by a BJT such as a PNP BJT with a saturation protection clamp. In some examples, the current source 312 is implemented by a FET such as a PMOS FET. In the example of FIG. 3, the input of the current source 312 is coupled to the voltage terminal 320. Also, the output of the current source 312 is coupled to the first terminal of the transistor 310 and the first terminal of the transistor 346, which operates as the first output of the current mirror 314.

In the illustrated example of FIG. 3, the supply input of the current mirror 314, for example, the first terminal of the resistor 340 and the first terminal of the resistor 342, is coupled to the voltage terminal 320. In the example of FIG. 3, the first output of the current mirror 314, for example, the first terminal of the transistor 346, is coupled to the first terminal of the transistor 310 and the output of the current source 312. Also, the second output of the current mirror 314, for example, the first terminal of the transistor 344, is coupled to the first terminal of the load resistor 316 and the output 326.

In the illustrated example of FIG. 3, the first terminal of the resistor 342, which operates as the supply input of the current mirror 314, is coupled to the voltage terminal 320. In the example of FIG. 3, the second terminal of the resistor 342 is coupled to the second terminal of the transistor 346. Also, the first terminal of the resistor 340, which operates as the supply input of the current mirror 314, is coupled to the voltage terminal 320. In the example of FIG. 3, the second terminal of the resistor 340 is coupled to the second terminal of the transistor 344.

In the illustrated example of FIG. 3, the transistor 346 is implemented by a BJT such as a PNP BJT. In some examples, the transistor 346 is implemented by a FET such as a PMOS FET. In the example of FIG. 3, the control terminal of the transistor 346 is coupled to the first terminal of the transistor 346, the first terminal of the transistor 310, the output of the current source 312, and the control terminal of the transistor 344. Also, the first terminal of the transistor 346, which operates as the first output of the current mirror 314, is coupled to the control terminal of the transistor 346, the first terminal of the transistor 310, the output of the current source 312, and the control terminal of the transistor 344. In the example of FIG. 3, the second terminal of the transistor 346 is coupled to the second terminal of the resistor 342.

In the illustrated example of FIG. 3, the transistor 344 is implemented by a BJT such as a PNP BJT. In some examples, the transistor 344 is implemented by a FET such as a PMOS FET. In the example of FIG. 3, the control terminal of the transistor 344 is coupled to the control terminal of the transistor 346, the first terminal of the transistor 346, the first terminal of the transistor 310, and the output of the current source 312. Also, the first terminal of the transistor 344, which operates as the second output of the current mirror 314, is coupled to the first terminal of the load resistor 316 and the output 326. In the example of FIG. 3, the second terminal of the transistor 344 is coupled to the second terminal of the resistor 340.

In the illustrated example of FIG. 3, the load resistor 316 represents a load of the detector cell 300. For example, the load resistor 316 is a resistive load. In some examples, the load of the detector cell 300 is at least one of an inductive load, a capacitive load, or a resistive load. In the example of FIG. 3, the first terminal of the load resistor 316 is coupled to the first terminal of the transistor 336, which operates as the second output of the current mirror 308, the first terminal of the transistor 344, which operates as the second output of the current mirror 314, and the output 326. Also, the second terminal of the load resistor 316 is coupled to the output 328. In some examples, such as in an SDLA with a single ended output such as the SDLA 100 of FIG. 1B, the output 328 is coupled to the voltage terminal 318. As such, in such examples, the second terminal of the load resistor 316 is coupled to the voltage terminal 318.

In the illustrated example of FIG. 3, the output current signal I_{OUT} from the detector cell 300 is defined in Equation 3 below.

$${I}_{OUT} = {l}_{O} * \frac{1 - {e}^{- \frac{{V}_{IN}}{{V}_{t}}}}{2 * ( 1 + {e}^{\frac{{V}_{IN}}{{V}_{t}}} )} \qquad Equation 3$$

In Equation 3, I_{O} represents the current set by the current source 302, V_{IN} represents the voltage of an input signal V_{IN} (measured between the input 322 and the input 324) to the detector cell 300, and Vₜ represents the thermal voltage of the transistor 304 and the transistor 310. In the example of FIG. 3, the current through the transistor 304, I_{C1}, is defined according to Equation 4 below and the current through the transistor 310, I_{C2}, is defined according to Equation 5 below.

$${I}_{C 1} = \frac{{I}_{O}}{1 + {e}^{- \frac{{V}_{IN}}{{V}_{t}}}} \qquad Equation 4$$

$${I}_{C 2} = \frac{{I}_{O}}{1 + {e}^{- \frac{{V}_{IN}}{{V}_{t}}}} \qquad Equation 5$$

Also, in the illustrated example of FIG. 3, the current through the transistor 334, I₁, is defined according to Equation 6 below and the current through the transistor 346, I₂, is defined according to Equation 7 below.

$${I}_{1} = {I}_{C 1} - \frac{{I}_{O}}{2} \qquad Equation 6$$

$${I}_{2} = {I}_{C 2} - \frac{{I}_{O}}{2} \qquad Equation 7$$

As such, in example operation, when the voltage at the input 322, V_{IN+}, and the voltage at the input 324, V_{IN-}, are equal, then the current through the transistor 304, I_{C1}, and the current through the transistor 310, I_{C2}, will be equal to half of the current set by the current source 302. For example, I_{C1}=I_{C2}=I_{O}/2. Also, when the voltage at the input 322, V_{IN+}, is greater than the voltage at the input 324, V_{IN-}, then (1) the current through the transistor 304, I_{C1}, is equal to the sum of half of the current set by the current source 302 and a delta and (2) the current through the transistor 310, I_{C2}, is equal to the difference between half of the current set by the current source 302 and the delta. I_{C1}=I_{O}/2+ΔI and I_{C2}=I_{O}/2−ΔI. For example, there is a positive differential voltage between the input 322 and the input 324, in other words, V_{IN} is positive, when the voltage at the input 322 is greater than the voltage at the input 324.

In example operation, when the voltage at the input 322, V_{IN+}, is greater than the voltage at the input 324, V_{IN-}, then the current through the transistor 304 is greater than the current through the transistor 310, I_{C1}>I_{C2}). For example, there is a positive differential voltage between the input 322 and the input 324, in other words, V_{IN} is positive, when the voltage at the input 322, V_{IN+}, is greater than the voltage at the input 324, V_{IN-}. As such, if the voltage at the input 322, V_{IN+}, is greater than the voltage at the input 324, V_{IN-}, then the voltage at the first terminal of the transistor 310 will move to the voltage at the voltage terminal 320 and the current mirror 314 will be disabled. As such, the current through the transistor 304, I_{C1}, will be approximately equal to the current set by the current source 302, I_{C1}=I_{O} and I_{C2}=0.

Equation 8 below defines the current through the transistor 334, I₁, when the voltage at the input 322, V_{IN+}, is greater than the voltage at the input 324, V_{IN-}.

$$\begin{matrix}{I}_{1} = \frac{{I}_{O}}{1 + {e}^{\frac{{V}_{IN}}{{V}_{t}}}} - \frac{{I}_{O}}{2} \\ {I}_{1} = \frac{{I}_{O} * ( 1 - {e}^{- \frac{{V}_{IN}}{{V}_{t}}} )}{2 * ( 1 + {e}^{- \frac{{V}_{IN}}{{V}_{t}}} )}\end{matrix} \qquad Equation 8$$

Equation 9 below defines the current through the transistor 334, I₁, when the voltage at the input 322, V_{IN+}, between the input 324, V_{IN-}, is much less than the thermal voltage Vₜ of the transistor 304 and the transistor 310, V_{IN}<<Vₜ.

$${I}_{1} = \frac{{I}_{O} * \frac{{V}_{IN}}{{V}_{t}}}{2 * ( 2 - \frac{{V}_{IN}}{{V}_{t}} )} = \frac{{I}_{O} * \frac{{V}_{IN}}{{V}_{t}}}{\frac{4 * {V}_{t} - 2 * {V}_{IN}}{{V}_{t}}} \qquad Equation 9$$

As such, when the input voltage signal, V_{IN}, becomes much less than the terminal voltage Vₜ of the transistor 304 and the transistor 310, for example, for low magnitude input voltage signals, the current through the transistor 334, I₁, is defined according to Equation 10 below. Also, when the input voltage signal, V_{IN}, becomes much less than the terminal voltage Vₜ of the transistor 304 and the transistor 310, for example, for low magnitude input voltage signals, the output current signal, I_{OUT}, from the detector cell 300 is defined according to Equation 11 below. As illustrated in Equation 11, when the voltage at the input 322, V_{IN+}, between the input 324, V_{IN-}, is much less than the thermal voltage Vₜ of the transistor 304 and the transistor 310, V_{IN}<<Vₜ, the output current signal, I_{OUT}, is proportional to the input voltage signal, V_{IN}.

$${I}_{1} = {I}_{O} * \frac{{V}_{IN}}{4 * {V}_{t}} \qquad Equation 10$$

$${I}_{OUT} = {I}_{1} = {I}_{O} * \frac{{V}_{IN}}{4 * {V}_{t}} \qquad Equation 11$$

Equation 12 below defines the output current signal, I_{OUT}, from the detector cell 300 when the voltage at the input 322, V_{IN+}, between the input 324, V_{IN-}, is much greater than the thermal voltage Vₜ of the transistor 304 and the transistor 310, V_{IN}>>Vₜ.

$${I}_{OUT} = {I}_{1} = \frac{{I}_{O}}{2} \qquad Equation 12$$

Thus, in example operation, when the voltage of the input signal V_{IN} to the detector cell 300 is zero, V_{IN}=0, the output current signal from the detector cell 300 is near zero, I_{OUT}≈0. As such, the voltage of an output signal V_{OUT} (measured between the output 326 and the output 328) from the detector cell 300 is approximately zero, V_{OUT}≈0, when the voltage of the input signal V_{IN} is zero. Also, in example operation, when the absolute value of the voltage of the input signal V_{IN} to the detector cell 300 is greater than two times the thermal voltage Vₜ, |V_{IN}|>2*Vₜ, then the current through the transistor 304, I_{C1}, or the current through the transistor 310, I_{C2}, will dominate and the voltage of the output signal V_{OUT} from the detector cell 300 is equal to the product of half the current set by the current source 302 and the resistance of the load resistor 316, V_{OUT}=I_{O/2}*R_{L}.

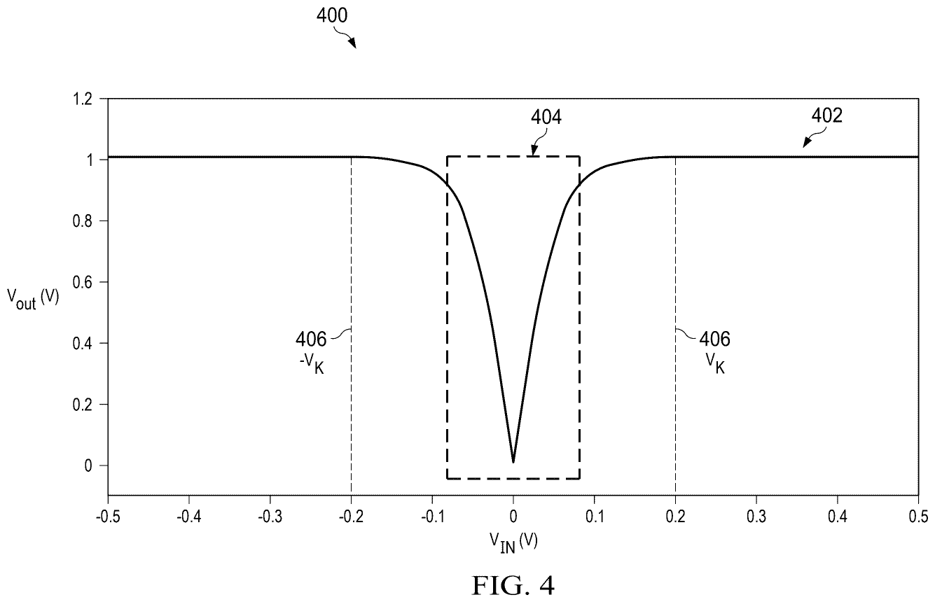

FIG. 4 is a graphical illustration of an example graph 400 depicting an example transfer function 402 of the detector cell 300 of FIG. 3. In the example of FIG. 4, the transfer function 402 represents the output voltage signal, V_{OUT}, from the detector cell 300 in volts as a function of the input voltage signal, V_{IN}, to the detector cell 300 in volts. Also, the transfer function 402 includes an example linear region 404 in which there is a linear dependence of the output voltage signal, V_{OUT}, on the input voltage signal, V_{IN}, for small input voltage signals, for example, V_{IN}=[−0.8, 0.8]. In the example of FIG. 4, the transfer function 402 includes an example saturation voltage 406, V_{K}, at which the detector cell 300 saturates as described above.

As illustrated in FIG. 4, when the voltage at the input 322, V_{IN+}, is less than the voltage at the input 324, V_{IN-}, then the current through the transistor 304 is less than the current through the transistor 310, I_{C1}<I_{C2}. For example, there is a negative differential voltage between the input 322 and the input 324, in other words, V_{IN} is negative, when the voltage at the input 322, V_{IN+}, is less than the voltage at the input 324, V_{IN-}. If the voltage at the input 322, V_{IN+}, is less than the voltage at the input 324, V_{IN-}, then the voltage at the first terminal of the transistor 304 will move to the voltage at the voltage terminal 320 and the current mirror 308 will be disabled.

As such, the current through the transistor 310, I_{C2}, will be approximately equal to the current set by the current source 302, I_{C2}=I_{O} and I_{C1}=0. Because the direction of the output current signal, I_{OUT}, remains consistent, regardless of whether the current mirror 308 or the current mirror 314 is active, whether the input voltage signal, V_{IN}, is positive or negative), the output voltage signal, V_{OUT}, remains positive, for example, rectifying the input voltage signal, V_{IN}. As illustrated in FIG. 4, regardless of how large the absolute value of the input voltage signal, V_{IN}, is, the output voltage signal, V_{OUT}, does not exceed, in other words, the output voltage signal, V_{OUT}, saturates at, the product of half the current set by the current source 302 and the resistance of the load resistor 316, V_{OUT}=I_{O/2}*R_{L}.

Returning to FIG. 3, as described above, in some examples, the current source 302, the transistor 304, the current source 306, the transistor 310, the current source 312, the transistor 334, the transistor 336, the transistor 344, and the transistor 346 are implemented by BJTs. For example, if the current source 302 is implemented by an NPN BJT, then the current source 306 and the current source 312 are implemented by PNP BJTs with saturation protection clamps, the transistor 304 and the transistor 310 are implemented by NPN BJTs, and the transistor 334, the transistor 336, the transistor 344, and the transistor 346 are implemented by PNP BJTs. In such examples, the transfer function of the detector cell 300 is similar to that shown in FIG. 4.

Also, as described above, in some examples, the current source 302, the transistor 304, the current source 306, the transistor 310, the current source 312, the transistor 334, the transistor 336, the transistor 344, and the transistor 346 are implemented by FETs. For example, if the current source 302 is implemented by an NMOS FET, then the current source 306 and the current source 312 are implemented by PMOS FETs, the transistor 304 and the transistor 310 are implemented by NMOS FETs, and the transistor 334, the transistor 336, the transistor 344, and the transistor 346 are implemented by PMOS FETs. In such examples, the transfer function of the detector cell 300 is similar to that shown in FIG. 4, but the detector cell 300 saturates less abruptly than illustrated in FIG. 4. For example, the output voltage signal V_{OUT} may still increase for a limited range of input voltage signals greater than the saturation voltage 406.

As such, implementing at least the transistor 304 and the transistor 310 as BJTs can reduce the LCE of an SDLA utilizing the detector cell 300 as compared to implementing at least the transistor 304 and the transistor 310 as FETs. Also, implementing at least the transistor 304 and the transistor 310 as BJTs can improve the minimum input detectability of an SDLA utilizing the detector cell 300 as compared to implementing at least the transistor 304 and the transistor 310 as FETs. However, as described above, implementing at least the transistor 304 and the transistor 310 as FETs provides a transfer function similar to that shown in FIG. 4, but the detector cell 300 saturates less abruptly than illustrated in FIG. 4.

In the illustrated example of FIG. 3, the transistor 304 and the transistor 310 are NPN BJTs. Alternatively, the transistor 304 and the transistor 310 may be n-channel FETs, n-channel metal-oxide semiconductor field-effect transistors (MOSFETs), n-channel insulated-gate bipolar transistors (IGBTs), n-channel junction field effect transistors (JFETs), or, with slight modifications, p-type equivalent devices. In the example of FIG. 3, the transistor 334, the transistor 336, the transistor 344, and the transistor 346 are PNP BJTs. Alternatively, the transistor 334, the transistor 336, the transistor 344, and the transistor 346 may be p-channel FETs, p-channel MOSFETs, p-channel IGBTs, p-channel JFETs, or, with slight modifications, N-type equivalent devices.

The transistor 304, the transistor 310, the transistor 334, the transistor 336, the transistor 344, and the transistor 346 may be depletion mode devices, drain-extended devices, enhancement mode devices, natural transistors, or other type of device structure transistors. Furthermore, the transistor 304, the transistor 310, the transistor 334, the transistor 336, the transistor 344, and the transistor 346 may be implemented in/over a silicon (Si) substrate, a silicon carbide (SiC) substrate, a gallium nitride (GaN) substrate or a gallium arsenide (GaAs) substrate. Also, in some examples, one or more of the components of any of FIG. 1A, 1B, or 3 is implemented by at least one of analog or digital circuitry.

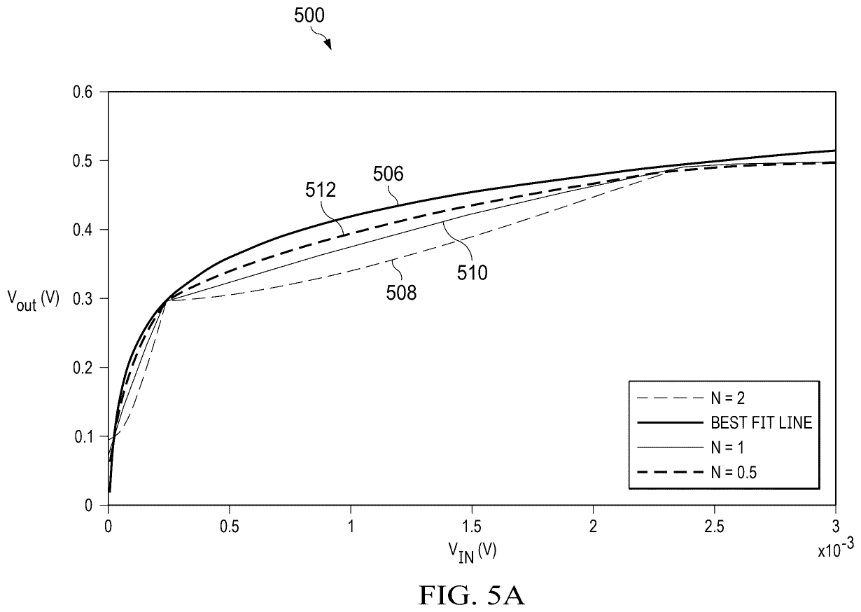

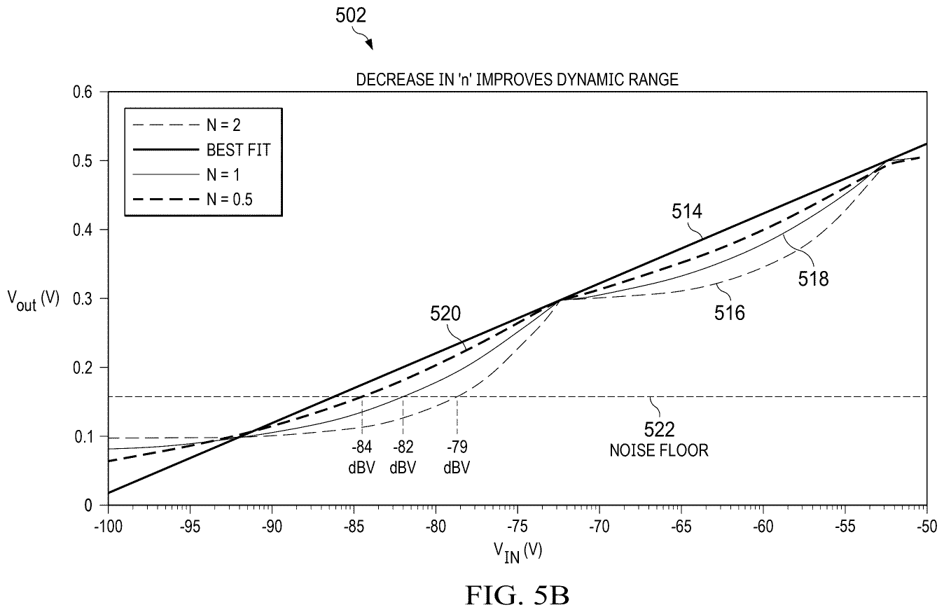

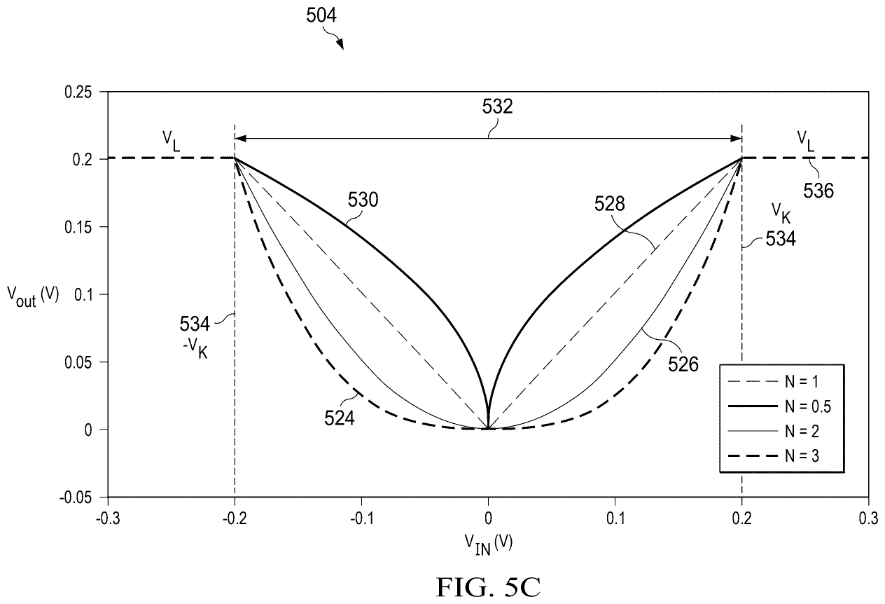

FIG. 5A is a graphical illustration of an example graph 500 depicting a relationship between a degree of a detector cell and LCE of an SDLA. In the example of FIG. 5A, the graph 500 depicts output voltage signal, V_{OUT}, in volts versus input voltage signal, V_{IN}, in volts. FIG. 5B is a graphical illustration of an example graph 502 depicting a relationship between a degree of a detector cell and DR of an SDLA. In the example of FIG. 5B, the graph 502 depicts output voltage signal, V_{OUT}, in volts versus input voltage signal, V_{IN}, in dBV. FIG. 5C is a graphical illustration of an example graph 504 depicting a relationship between the transfer function of a detector cell and a degree of the detector cell. In the example of FIG. 5C, the graph 504 depicts output voltage signal, V_{OUT}, in volts versus input voltage signal, V_{IN}, in volts.

In the illustrated example of FIGS. 5A, 5B, and 5C, the degree of a detector cell refers to the mathematical relationship between the input voltage signal and the output voltage signal of the detector cell before saturation. In the example of FIG. 5A, the graph 500 includes a first example plot 506 depicting output voltage signal versus input voltage signal of an SDLA having an ideal logarithmic relationship between the input voltage signal and the output voltage signal. Also, the graph 500 includes a second example plot 508 depicting output voltage signal versus input voltage signal of an SDLA including a detector cell with a degree of two. In the example of FIG. 5A, the graph 500 includes a third example plot 510 depicting output voltage signal versus input voltage signal of an SDLA including a detector cell, for example, the detector cell 300 of FIG. 3, with a degree of one. Also, the graph 500 includes a fourth example plot 512 depicting output voltage signal versus input voltage signal of an SDLA including a detector cell with a degree of 0.5. In the example of FIG. 5A, as the degree of a detector cell decreases, the piecewise approximation of a logarithmic function by an SDLA having the detector cell improves. As such, as the degree of a detector cell decreases, the LCE of an SDLA having the detector cell decreases.

In the illustrated example of FIG. 5B, the graph 502 includes a first example plot 514 depicting output voltage signal versus input voltage signal of an SDLA having an ideal logarithmic relationship between the input voltage signal and the output voltage signal. Also, the graph 502 includes a second example plot 516 depicting output voltage signal versus input voltage signal of an SDLA including a detector cell with a degree of two. In the example of FIG. 5B, the graph 502 includes a third example plot 518 depicting output voltage signal versus input voltage signal of an SDLA including a detector cell, for example, the detector cell 300 of FIG. 3, with a degree of one. Also, the graph 502 includes a fourth example plot 520 depicting output voltage signal versus input voltage signal of an SDLA including a detector cell with a degree of 0.5. In the example of FIG. 5B, as the degree of a detector cell decreases, the detector cell can detect smaller signals above an example noise floor 522 of the detector cell. As such, as the degree of a detector cell decreases, the dynamic range of an SDLA having the detector cell increases.

In the illustrated example of FIG. 5C, the graph 504 includes a first example plot 524 depicting output voltage signal versus input voltage signal of an SDLA including a detector cell with a degree of three. Also, the graph 504 includes a second example plot 526 depicting output voltage signal versus input voltage signal of an SDLA including a detector cell with a degree of two. In the example of FIG. 5C, the graph 504 includes a third example plot 528 depicting output voltage signal versus input voltage signal of an SDLA including a detector cell, for example, the detector cell 300 of FIG. 3, with a degree of one. Also, the graph 504 includes a fourth example plot 530 depicting output voltage signal versus input voltage signal of an SDLA including a detector cell with a degree of 0.5.

In the illustrated example of FIG. 5C, the graph 504 includes an example non-saturation region 532 in which the detector cells of the plot 524, the plot 526, the plot 528, and the plot 530 are not saturated. In the example of FIG. 5C, the output voltage signal of a detector cell is defined as illustrated in Equation 13 below.

$${V}_{OUT} = {V}_{L} * {( \frac{{V}_{IN}}{{V}_{K}} )}^{N} \qquad Equation 13$$

In Equation 13, V_{OUT} represents the output voltage signal of a detector cell, V_{IN} represents the input voltage signal to the detector cell, V_{K} represents an example saturation voltage 534 at which the detector cell saturates, V_{L} represents an example saturated voltage 536 for the detector cell, and N represents a degree of the detector cell. As illustrated in FIG. 5C, as the degree of a detector cell decreases, the gain of the detector cell increases for input voltage signals around the center of the non-saturation region 532 and the gain of the detector cell decreases at the edge of the non-saturation region 532. Table 1 below illustrates the LCE of an SDLA in dB and minimum detectable input signal of the SDLA in microvolts (μV) at the LCE for a detector cell at different degrees. In Table 1, the values correspond to an SDLA where the gain, A, of each amplifier stage of the SDLA is 10, the saturation voltage V_{K} is 200 millivolts (mV), and the saturated voltage V_{L} is 200 mV.

TABLE 1

| | | Minimum Input Signal |
|---|---|---|
| N | LCE (dB) | Detectable |
| 2 | ±3.8 | 21 μV (±5 dB) |
| 1 | ±2 | 16 μV (±5 dB) |
| 0.5 | ±1.33 | 9 μV (±5 dB) |

As illustrated in FIGS. 5A, 5B, and 5C, as the degree of a detector cell decreases, the LCE of an SDLA including the detector cell reduces and the DR of the SDLA including the detector cell increases. Thus, a detector cell, such as the detector cell 300 of FIG. 3, having a degree of one provides a linear transfer function in the non-saturation region 532 while also improving the LCE and DR of an SDLA including the detector cell.

Table 2 below illustrates the LCE and DR of an SDLA when utilizing the detector cell 300 of FIG. 3 and the LCE and DR of the SDLA when utilizing another detector cell. In Table 2, the other detector cell has a degree of two. As described above, the detector cell 300 of FIG. 3 has a degree of one. In Table 2, the values correspond to an SDLA with a fixed number of amplifier stages, the same gain, A, in each amplifier stage, a fixed noise floor, and a fixed quiescent current, I_{Q}. As illustrated in Table 2, the minimum input detectability of the SDLA improves by 6 dB in peak voltage (V_{P}) and the LCE of the SDLA reduces by 0.6 dB for the same quiescent current when utilizing the detector cell 300 of FIG. 3, with a degree of one, as compared to the other detector cell, with a degree of two.

TABLE 2

| Specification | Detector Cell 300 | | Other Detector Cell | |
|---|---|---|---|---|
| I_{Q} | 3.7 milliamps | (mA) | 3.7 | mA |
| LCE | ±0.5 | dB | ±1.1 | dB |
| Input Signal Range | 14 μV_{P}-2 V_{P} | (±2 dB) | 28 μV_{P}-2 V_{P} | (±2 dB) |
| Dynamic Range | 100 dB | (±1 dB) | 94 dB | (±1 dB) |
| | 103 dB | (±2 dB) | 97 dB | (±2 dB) |

Table 3 below illustrates the quiescent current of an SDLA when utilizing the detector cell 300 of FIG. 3 and the quiescent current of the SDLA when utilizing another detector cell. In Table 3, the other detector cell has a degree of two. As described above, the detector cell 300 of FIG. 3 has a degree of one. In Table 3, the values for the detector cell 300 correspond to an SDLA with four amplifier stages, a gain, A, of 10 in each amplifier stage, and a quiescent current, I_{Q}, of 1.56 mA. Also, in the Table 3, the values for the other detector cell correspond to an SDLA with five amplifier stages, a gain, A, of 6.7 in each amplifier stage, and a quiescent current, I_{Q}, of 2.64 mA, which is a two times reduction in quiescent current, I_{Q}. As illustrated in Table 3, the quiescent current of an SDLA improves by 1.08 mA for the same LCE and DR when utilizing the detector cell 300 of FIG. 3, with a degree of one, as compared to the other detector cell, with a degree of two.

TABLE 3

| Specification | Detector Cell 300 | | Other Detector Cell | |
|---|---|---|---|---|
| I_{Q} | 1.56 | mA | 2.64 | mA |
| LCE | ±0.5 | dB | ±0.5 | dB |
| Input Signal Range | 20 μV_{P}-2 V_{P} | (±1 dB) | 20 μV_{P}-2 V_{P} | (±2 dB) |
| Dynamic Range | 100 dB | (±1 dB) | 100 dB | (±1 dB) |

While an example manner of implementing the detector cell 300 of FIG. 3 is illustrated in FIG. 3, one or more of the elements, processes, or devices illustrated in FIG. 3 may be combined, divided, re-arranged, omitted, eliminated, or implemented in any other way. Further, the example detector cell 300 of FIG. 3, may be implemented by hardware alone or by hardware in combination with software and firmware. Thus, for example, the example detector cell 300 of FIG. 3, could be implemented by programmable circuitry in combination with one or more machine-readable instructions, for example, firmware or software, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example detector cell 300 of FIG. 3 may include one or more elements, processes, or devices in addition to, or instead of, those illustrated in FIG. 3, or may include more than one of any or all of the illustrated elements, processes, and devices.

“Including” and “comprising” (and all forms and tenses thereof) are used herein to be open ended terms. Thus, whenever a claim employs any form of “include” or “comprise” as a preamble or within a claim recitation of any kind, additional elements, terms, etc., may be present without falling outside the scope of the corresponding claim or recitation. Examples forms of “include” and “comprise” include comprise, include, comprises, includes, comprising, including, having, etc. As used herein, when the phrase “at least” is used as the transition term in, for example, a preamble of a claim, it is open-ended in the same manner as the term “comprising” and “including” are open ended. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references do not exclude a plurality. Examples of singular references include “a,” “an,” “first,” “second,” etc. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, for example, the same entity or object. Also, although individual features may be included in different examples or claims, these may possibly be combined, and the inclusion in different examples or claims does not imply that a combination of features is at least one of not feasible or advantageous.

As used herein, connection references, for example, attached, coupled, connected, and joined, may include intermediate members between the elements referenced by at least one of the connection reference or relative movement between those elements unless otherwise indicated. As such, connection references do not necessarily infer that two elements are directly connected or in fixed relation to each other.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion, for example, within a claim, in which the elements might, for example, otherwise share a same name.

As used herein, the phrase “in communication,” including variations thereof, encompasses one of or a combination of direct communication or indirect communication through one or more intermediary components, and does not require direct physical, for example, wired, communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits, for example, an application specific circuit (ASIC), structured to perform specific operation(s) and including one or more semiconductor-based logic devices, for example, electrical hardware implemented by one or more transistors, or (ii) one or more general purpose semiconductor-based electrical circuits programmable with instructions to perform one or more specific functions(s) or operation(s) and including one or more semiconductor-based logic devices, for example, electrical hardware implemented by one or more transistors. Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry, for example, one or more FPGAs, one or more CPUs, one or more GPUs, one or more NPUs, one or more DSPs, etc., and any combination(s) thereof, and orchestration technology, for example, application programming interface(s) (API(s), that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured, for example, at least one of programmed or hardwired, at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage or current sources) may instead include only the semiconductor elements within a single physical device, for example, at least one of a semiconductor die or integrated circuit (IC) package, and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. Unless otherwise stated, “about,” “approximately,” or “substantially” preceding a value means +/−10 percent of the stated value, or, if the value is zero, a reasonable range of values around zero.

Modifications are possible in the described examples, and other examples are possible, within the scope of the claims.

From the foregoing, it will be appreciated that example systems, apparatus, articles of manufacture, and methods have been described that reduce the LCE of a logarithmic amplifier, improve minimum input detectability of a logarithmic amplifier, and increase the dynamic range of a logarithmic amplifier. For example, described detector cells have a linear transfer function, for example, as opposed to a non-linear transfer function. By implementing a detector cell with a linear transfer function to improve conformance to a non-linear, logarithmic function of a logarithmic amplifier, examples described herein reduce the LCE of the logarithmic amplifier for a given gain, A, per amplifier stage without compromising on dynamic range of the logarithmic amplifier, area consumption by the logarithmic amplifier on chip, power consumption of the logarithmic amplifier, or minimum input detectability of the logarithmic amplifier.

Also, by improving LCE of a logarithmic amplifier as described herein, the gain, A, per amplifier stage of the logarithmic amplifier can be increased while attaining the same LCE as other approaches. As such, the number of amplifier stages, N, of a logarithmic amplifier can be reduced while attaining the same dynamic range as other approaches. Described examples reduce the number of amplifier stages, N, of a logarithmic amplifier by 20% and reduce the quiescent current of the logarithmic amplifier by 40% while attaining the same minimum input detectability and dynamic range as other approaches. Also, described examples improve the minimum input detectability by two times as compared to other approaches and facilitate two times the dynamic range while attaining the same area and power consumption as other approaches. Described systems, apparatus, articles of manufacture, and methods improve the efficiency of using a computing device by reducing the area and power consumption of a logarithmic amplifier.

Described systems, apparatus, articles of manufacture, and methods are also directed to one or more improvement(s) in the operation of a machine such as a computer or other electronic, electromechanical, or mechanical device.

What is claimed is:

1. A detector cell comprising:
a first current source circuit having a terminal;
a first transistor having a control terminal, a first terminal, and a second terminal coupled to the terminal of the first current source circuit;
a second current source circuit having a terminal coupled to the first terminal of the first transistor;
a first current mirror having a first terminal and a second terminal, the first terminal coupled to the terminal of the second current source circuit and the first terminal of the first transistor;
a second transistor having a control terminal, a first terminal, and a second terminal coupled to the terminal of the first current source circuit;
a third current source circuit having a terminal coupled to the first terminal of the second transistor; and
a second current mirror having a first terminal coupled to the terminal of the third current source circuit and the first terminal of the second transistor and a second terminal coupled to the second terminal of the first current mirror.

2. The detector cell of claim 1, further including a resistor having a terminal coupled to the second terminal of the first current mirror and the second terminal of the second current mirror.

3. The detector cell of claim 1, wherein respective ones of the first current mirror and the second current mirror include:
a first resistor having a first terminal and a second terminal;
a third transistor having a control terminal, a first terminal, and a second terminal, the control terminal coupled to the first terminal, the first terminal to operate as the first terminal of the respective ones of the first current mirror and the second current mirror, the second terminal coupled to the second terminal of the first resistor;
a fourth transistor having a control terminal, a first terminal, and a second terminal, the control terminal coupled to the control terminal of the third transistor, the first terminal to operate as the second terminal of the respective ones of the first current mirror and the second current mirror; and
a second resistor having a first terminal coupled to the first terminal of the first resistor and a second terminal coupled to the second terminal of the fourth transistor.

4. The detector cell of claim 1, wherein:
at least one of the second current source circuit or the third current source circuit is implemented by a positive-negative-positive bipolar junction transistor (BJT); and
the first current source circuit is implemented by a negative-positive-negative BJT.

5. The detector cell of claim 1, wherein:
at least one of the second current source circuit or the third current source circuit is implemented by a positive-channel metal-oxide-semiconductor field-effect transistor (MOSFET); and
the first current source circuit is implemented by a negative-channel MOSFET.

6. The detector cell of claim 1, wherein at least one of the first transistor or the second transistor is implemented by a negative-positive-negative bipolar junction transistor.

7. The detector cell of claim 1, wherein at least one of the first transistor or the second transistor is implemented by a negative-channel metal-oxide-semiconductor field-effect transistor.

8. A logarithmic amplifier comprising:
a first detector cell having a first terminal, a second terminal, and a third terminal;
an amplifier having a first terminal, a second terminal, a third terminal coupled to the second terminal of the first detector cell, and a fourth terminal coupled to the third terminal of the first detector cell;
a second detector cell having a first terminal, a second terminal coupled to the first terminal of the amplifier, and a third terminal coupled to the second terminal of the amplifier;
an adder having a first terminal, a second terminal coupled to the first terminal of the first detector cell, and a third terminal coupled to the first terminal of the second detector cell, respective ones of the first detector cell and the second detector cell including:
a first current source circuit having a terminal;
a first transistor having a control terminal, a first terminal, and a second terminal, the control terminal to operate as the second terminal of the respective ones of the first detector cell and the second detector cell, the second terminal coupled to the terminal of the first current source circuit;
a second current source circuit having a terminal coupled to the first terminal of the first transistor;
a first current mirror having a first terminal coupled to the terminal of the second current source circuit and the first terminal of the first transistor and a second terminal to operate as the first terminal of the respective ones of the first detector cell and the second detector cell;
a second transistor having a control terminal, a first terminal, and a second terminal, the control terminal to operate as the third terminal of the respective ones of the first detector cell and the second detector cell, the second terminal coupled to the terminal of the first current source circuit;
a third current source circuit having a terminal coupled to the first terminal of the second transistor; and
a second current mirror having a first terminal coupled to the terminal of the third current source circuit and the first terminal of the second transistor and a second terminal coupled to the second terminal of the first current mirror and to operate as the first terminal of the respective ones of the first detector cell and the second detector cell.

9. The logarithmic amplifier of claim 8, wherein the amplifier is a first amplifier, the adder is a first adder, and the logarithmic amplifier includes:
a second amplifier having a first terminal, a second terminal, a third terminal coupled to the first terminal of the first amplifier, and a fourth terminal coupled to the second terminal of the first amplifier;
a third detector cell having a first terminal, a second terminal coupled to the first terminal of the second amplifier, and a third terminal coupled to the second terminal of the second amplifier;
a third amplifier having a first terminal, a second terminal, a third terminal coupled to the first terminal of the second amplifier, and a fourth terminal coupled to the second terminal of the second amplifier;
a fourth detector cell having a first terminal, a second terminal coupled to the first terminal of the third amplifier, and a third terminal coupled to the second terminal of the third amplifier;
a second adder having a first terminal, a second terminal coupled to the first terminal of the third detector cell, and a third terminal coupled to the first terminal of the fourth detector cell;
a third adder having a first terminal, a second terminal coupled to the first terminal of the first adder, and a third terminal coupled to the first terminal of the second adder; and
a filter having a first terminal and a second terminal coupled to the first terminal of the third adder, respective ones of the third detector cell and the fourth detector cell including:
a fourth current source circuit having a terminal;
a third transistor having a control terminal, a first terminal, and a second terminal, the control terminal to operate as the second terminal of the respective ones of the third detector cell and the fourth detector cell, the second terminal coupled to the terminal of the fourth current source circuit;
a fifth current source circuit having a terminal coupled to the first terminal of the third transistor;
a third current mirror having a first terminal coupled to the terminal of the fifth current source circuit and the first terminal of the third transistor, and a second terminal to operate as the first terminal of the respective ones of the third detector cell and the fourth detector cell;
a fourth transistor having a control terminal, a first terminal, and a second terminal, the control terminal to operate as the third terminal of the respective ones of the third detector cell and the fourth detector cell, the second terminal coupled to the terminal of the fourth current source circuit;
a sixth current source circuit having a terminal coupled to the first terminal of the fourth transistor; and
a fourth current mirror having a first terminal coupled to the terminal of the sixth current source circuit and the first terminal of the fourth transistor and a second terminal coupled to the second terminal of the third current mirror and to operate as the first terminal of the respective ones of the third detector cell and the fourth detector cell.

10. The logarithmic amplifier of claim 8, wherein the respective ones of the first detector cell and the second detector cell further include a resistor having a first terminal coupled to the second terminal of the first current mirror and the second terminal of the second current mirror, the first terminal to operate as the first terminal of the respective ones of the first detector cell and the second detector cell.

11. The logarithmic amplifier of claim 8, wherein respective ones of the first current mirror and the second current mirror include:
a first resistor having a first terminal and a second terminal;
a third transistor having a control terminal, a first terminal, and a second terminal, the control terminal coupled to the first terminal, the first terminal to operate as the first terminal of the respective ones of the first current mirror and the second current mirror, the second terminal coupled to the second terminal of the first resistor;
a fourth transistor having a control terminal, a first terminal, and a second terminal, the control terminal coupled to the control terminal of the third transistor, the first terminal to operate as the second terminal of the respective ones of the first current mirror and the second current mirror; and
a second resistor having a first terminal coupled to the first terminal of the first resistor and a second terminal coupled to the second terminal of the fourth transistor.

12. The logarithmic amplifier of claim 8, wherein:
at least one of the second current source circuit or the third current source circuit is implemented by a positive-negative-positive bipolar junction transistor (BJT); and
the first current source circuit is implemented by a negative-positive-negative BJT.

13. The logarithmic amplifier of claim 8, wherein:
at least one of the second current source circuit or the third current source circuit is implemented by a positive-channel metal-oxide-semiconductor field-effect transistor (MOSFET); and
the first current source circuit is implemented by a negative-channel MOSFET.

14. The logarithmic amplifier of claim 8, wherein at least one of the first transistor or the second transistor is implemented by a negative-positive-negative bipolar junction transistor.

15. The logarithmic amplifier of claim 8, wherein at least one of the first transistor or the second transistor is implemented by a negative-channel metal-oxide-semiconductor field-effect transistor.

16. A logarithmic amplifier having a non-linear transfer function, the logarithmic amplifier comprising:
a first detector cell having a first terminal, a second terminal, and a third terminal, the first detector cell having a first linear transfer function;
an amplifier having a first terminal, a second terminal, a third terminal coupled to the second terminal of the first detector cell, and a fourth terminal coupled to the third terminal of the first detector cell;
a second detector cell having a first terminal, a second terminal coupled to the first terminal of the amplifier, and a third terminal coupled to the second terminal of the amplifier, the second detector cell having a second linear transfer function; and
an adder having a first terminal, a second terminal coupled to the first terminal of the first detector cell, and a third terminal coupled to the first terminal of the second detector cell.

17. The logarithmic amplifier of claim 16, wherein the amplifier is a first amplifier, the adder is a first adder, and the logarithmic amplifier includes:
a second amplifier having a first terminal, a second terminal, a third terminal coupled to the first terminal of the first amplifier, and a fourth terminal coupled to the second terminal of the first amplifier;
a third detector cell having a first terminal, a second terminal coupled to the first terminal of the second amplifier, and a third terminal coupled to the second terminal of the second amplifier, the third detector cell having a third linear transfer function;
a third amplifier having a first terminal, a second terminal, a third terminal coupled to the first terminal of the second amplifier, and a fourth terminal coupled to the second terminal of the second amplifier;
a fourth detector cell having a first terminal, a second terminal coupled to the first terminal of the third amplifier, and a third terminal coupled to the second terminal of the third amplifier, the fourth detector cell having a fourth linear transfer function;
a second adder having a first terminal, a second terminal coupled to the first terminal of the third detector cell, and a third terminal coupled to the first terminal of the fourth detector cell;
a third adder having a first terminal, a second terminal coupled to the first terminal of the first adder, and a third terminal coupled to the first terminal of the second adder; and
a filter having a first terminal and a second terminal coupled to the first terminal of the third adder.

18. The logarithmic amplifier of claim 16, wherein respective ones of the first detector cell and the second detector cell are to rectify respective input voltage signals.

19. The logarithmic amplifier of claim 16, wherein respective output voltage signals from respective ones of the first detector cell and the second detector cell are to saturate after respective input voltage signals to the respective ones of the first detector cell and the second detector cell reach a saturation voltage.

20. The logarithmic amplifier of claim 16, wherein respective ones of the first detector cell and the second detector cell are to improve a logarithmic conformance error and a dynamic range of the logarithmic amplifier.
